(19) United States
(12) Patent Application Publication
(10) Pub. No.: US 2017/0254865 A1
(43) Pub. Date: Sep. 7, 2017

(54) A MAGNETIC RESONANCE APPARATUS COMPRISING A PLASMA ANTENNA

(71) Applicants: ACADEMISCH ZIEKENHUIS LEIDEN, Leiden (NL); HALEAKALA R&D, INC., Brookfield, MA (US)

(72) Inventors: Sebastian Aussenhofer, Leiden (NL); Andrew Webb, Leiden (NL); Theodore Anderson, Brookfield, MA (US); Fred Deyer, Tazewell, TN (US)

(21) Appl. No.: 15/511,389

(22) PCT Filed: Sep. 15, 2015
(86) PCT No.: PCT/EP2015/071108

§ 371 Date: Mar. 15, 2017

(30) Foreign Application Priority Data
Sep. 16, 2014 (GB) 1416363.8

(51) Int. Cl. G01R 33/34; H01Q 1/26; G01R 33/48; H01Q 5/22; G01R 33/36; G01R 33/421

(52) U.S. Cl. CPC G01R 33/34007; G01R 33/365; G01R 33/3635; G01R 33/3657; G01R 33/421; G01R 33/4808; H01Q 5/22; H01Q 1/26; H05H 1/24

(57) ABSTRACT

A magnetic resonance apparatus comprising: a magnetic system configured to provide a magnetic field throughout at least a portion of a cavity, the magnetic field based on magnetic-system-control-data; a transmitter antenna disposed at least partly within the cavity and configured to transmit radio-frequency-transmitted-signalling based on transmitter-control-data; and a receiver antenna disposed at least partly within the cavity and configured to receive radio-frequency-received-signalling representative of magnetic resonance interactions of at least one object, disposed within the portion of the cavity, with the magnetic field and the radio-frequency-transmitted-signalling; wherein, at least one of the transmitter antenna, the receiver antenna and the magnetic system comprises a plasma antenna, and the magnetic resonance imaging apparatus is configured to provide received-data representative of the radio-frequency-received-signalling, the received-data in combination with the magnetic-system-control-data and the transmitter-control-data suitable for providing magnetic resonance imaging and/or magnetic resonance spectroscopy of the at least one object.

The present disclosure relates to the field of magnetic resonance imaging and/or spectroscopy and in particular, although not necessarily, magnetic resonance imaging and/or spectroscopy based on nuclear magnetic resonance or electron spin resonance.

According to a first aspect of the invention, there is provided a magnetic resonance apparatus comprising:
a magnetic system configured to provide a magnetic field throughout at least a portion of a cavity, the magnetic field based on magnetic-system-control-data;
a transmitter antenna disposed at least partly within the cavity and configured to transmit radio-frequency-transmitted-signalling based on transmitter-control-data; and
a receiver antenna disposed at least partly within the cavity and configured to receive radio-frequency-received-signalling representative of magnetic resonance interactions of at least one object, disposed within the portion of the cavity, with the magnetic field and the radio-frequency-transmitted-signalling;
wherein:
   at least one of the transmitter antenna, the receiver antenna and the magnetic system comprises a plasma antenna; and
   the magnetic resonance apparatus is configured to provide received-data representative of the radio-frequency-received-signalling, the received-data in combination with the magnetic-system-control-data and the transmitter-control-data, wherein the received-data is suitable for providing magnetic resonance imaging (MRI) and/or magnetic resonance spectroscopy (MRS) of the at least one object.

Use of a plasma antenna may provide for more cost effective construction of a magnetic resonance apparatus than other types of antenna and can provide a good signal to noise ratio (SNR).

The transmitter antenna may be a first plasma antenna and/or the receiver antenna may be a second plasma antenna.

The transmitter antenna may comprise a plurality of plasma antennae. Use of a plurality of antennae may enable efficient transmission of radio frequency signalling throughout a larger volume of the cavity than a single plasma antenna.

The receiver antenna may comprise a plurality of plasma antennae. Use of a plurality of antennae may enable efficient reception of radio frequency signalling throughout a larger volume of the cavity than a single plasma antenna and provide for accelerated data acquisition.

The plasma antenna may comprise an ionized gas plasma antenna with a containment envelope configured to contain a vapour, which may be low pressure, the vapour suitable for forming an ionized gas plasma.

The ionized gas plasma antenna may comprise a first electrode contained within the containment envelope and a second electrode. The ionized gas plasma antenna may comprise multiple electrodes either contained within the containment envelope or mounted on the outside of the containment envelope. The first electrode or multiple electrodes may be configured to communicate the radio-frequency-transmitted-signalling and/or the radio-frequency-received-signalling. The first electrode or electrodes may be configured to communicate in-phase and quadrature phase radio-frequency-transmitted-signalling and/or radio-frequency-received-signalling. Multiple frequencies might be fed into the ionized gas plasma antenna via one or multiple electrodes allowing simultaneous or serial acquisition of information relating to different nuclei. Multiple electrodes may be configured to communicate in-phase and quadrature phase radio-frequency-transmitted-signalling or radio-frequency-received-signalling to the same plasma antennae.

The containment envelope may have a proximal end and a distal end. The first electrode may be contained within the proximal end of the containment envelope and may be in electrical communication with a first terminal disposed outside of the containment envelope. The ionized gas plasma antenna may further comprise a second electrode contained within the distal end of the containment envelope, wherein the second electrode may be in electrical communication with a second terminal disposed outside of the containment envelope. The first terminal and the second terminal may be configured to supply at least one of a Direct Current and an Alternating Current to the ionized gas plasma antenna.

The containment envelope may have a proximal end and a distal end. The first electrode may be in electrical communication with a first terminal disposed outside of the containment envelope. The ionized gas plasma antenna may further comprise a second electrode disposed outside of the containment envelope, which may be galvanically isolated from the first electrode. The second electrode may be in electrical communication with a second terminal disposed outside of the containment envelope. The first terminal and the second terminal may be configured to provide electrical power, for example in the form of Direct Current and/or an Alternating Current, to the ionized gas plasma antenna.

The ionized gas plasma antenna, may have a proximal end and a distal end, and may comprise:
a first electrode, with a first end and a second end, contained within the proximal end of the containment envelope and a first terminal disposed outside of the containment envelope in electrical communication with the first end of the first electrode; and
a second terminal disposed outside of the containment envelope, the second terminal in electrical communication with at least one of:
   a second electrode disposed outside of the containment envelope and galvanically isolated from the first electrode;
   the second end of the first electrode;
wherein, the first terminal and the second terminal may be configured to provide electrical power to the ionized gas plasma antenna.

The ionized gas plasma antenna may further comprise an igniter, disposed either outside or inside of the containment envelope, for igniting the vapour to form the ionized gas plasma, wherein the igniter may comprise one or more of:
a laser;
a device configured to produce a static or alternating magnetic field such as a tesla coil;
a high or low voltage Direct Current source;
a high or low voltage Alternating Current source;
a radio frequency source; and
a microwave source.

The ionized gas plasma antenna, may have a proximal end and a distal end, and may further comprise:
a first electrode, with a proximal end and a distal end, contained within the proximal end of the containment envelope and a first terminal disposed outside of the containment envelope in electrical communication with the proximal end of the first electrode; and
a second terminal disposed outside of the containment envelope, the second terminal in electrical communication with at least one of:
   a second electrode disposed outside of the containment envelope and galvanically isolated from the first electrode;
   the distal end of the first electrode; and
   a distal electrode contained within the distal end of the containment envelope;

wherein, the first terminal and the second terminal may be configured to provide electrical power to the ionized gas plasma antenna.

The containment envelope may comprise at least one of:
a linear envelope, comprising a distal end and a proximal end spaced apart longitudinally, the containment envelope extending therebetween; and
a circular/curved/non-linear envelope, comprising a loop of containment envelope extending around a central void.

The transmitter antenna may be a first ionized gas plasma antenna comprising a first containment envelope configured to contain a first vapour, the first vapour suitable for forming a first ionized gas plasma; and the receiver antenna may be a second ionized gas plasma antenna comprising a second containment envelope configured to contain a second vapour, different than the first vapour, the second vapour suitable for forming a second ionized gas plasma. The second ionized gas plasma is different to the first ionized gas plasma.

The transmitter antenna may also be the receiver antenna.

The plasma antenna may comprise metal components and a shielding. The shielding may be configured to electromagnetically shield the metal components from the magnetic field in the cavity. The shielding of metal components may prevent interference and improve signal to noise ratios for the magnetic resonance apparatus.

There may be provided at least one of:
a Positron Emission Tomography scanner disposed within the cavity, the Positron Emission Tomography scanner having a void for receiving an object to be scanned;
a Single-Photon Emission computed tomography scanner disposed within the cavity, the Single-Photon Emission computed tomography scanner having a void for receiving an object to be scanned; and
a computed tomography scanner disposed within the cavity, the computed tomography scanner having a void for receiving an object to be scanned.

The transmitter antenna and the receiver antenna may be disposed within the void of such scanners. Disposing a plasma antenna within the void of a scanner may not cause significant distortion or interference with the scanning of an object in the void, while simultaneously enabling magnetic resonance imaging and/or spectroscopy of the object.

The magnetic system may comprise a magnetic gradient system. The magnetic gradient system may comprise a plasma antenna configured to provide magnetic field gradients

The plasma antenna may comprise a fluorescent tube/lamp. A fluorescent tube is a readily available example of a plasma antenna that may be used in apparatus embodiments of the present disclosure.

The magnetic resonance apparatus may be a magnetic resonance imaging apparatus or a magnetic resonance spectroscopy apparatus.

There may be provided a plasma antenna comprising a containment envelope with an arbitrary shape for providing a volume for the vapour that can be ignited into an ionized plasma. The containment envelope may comprise any electric or dielectric material.

Either the transmit and/or the receiver antennae may comprise a combination of conventional lumped element antennae and plasma antenna.

The transmit and/or the receiver antennae may consist of a combination of conventional lumped elements and plasma cavities that may be switchable.

Examples of the invention will now be described in detail with reference to the accompanying figures, in which:

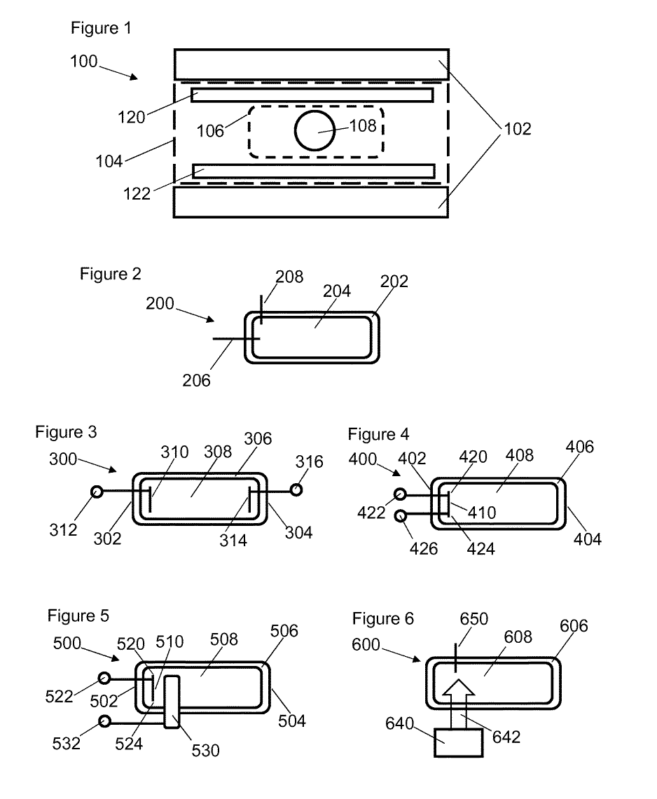

FIG. 1 illustrates a cross section view of a magnetic resonance apparatus, with a plasma antenna, suitable for providing magnetic resonance imaging and/or magnetic resonance spectroscopy of an object;

FIG. 2 illustrates a plasma antenna;

FIG. 3 illustrates an ionized gas plasma antenna;

FIG. 4 illustrates another ionized gas plasma antenna;

FIG. 5 illustrates a further still ionized gas plasma antenna;

FIG. 6 illustrates an ionized gas plasma antenna with an external igniter;

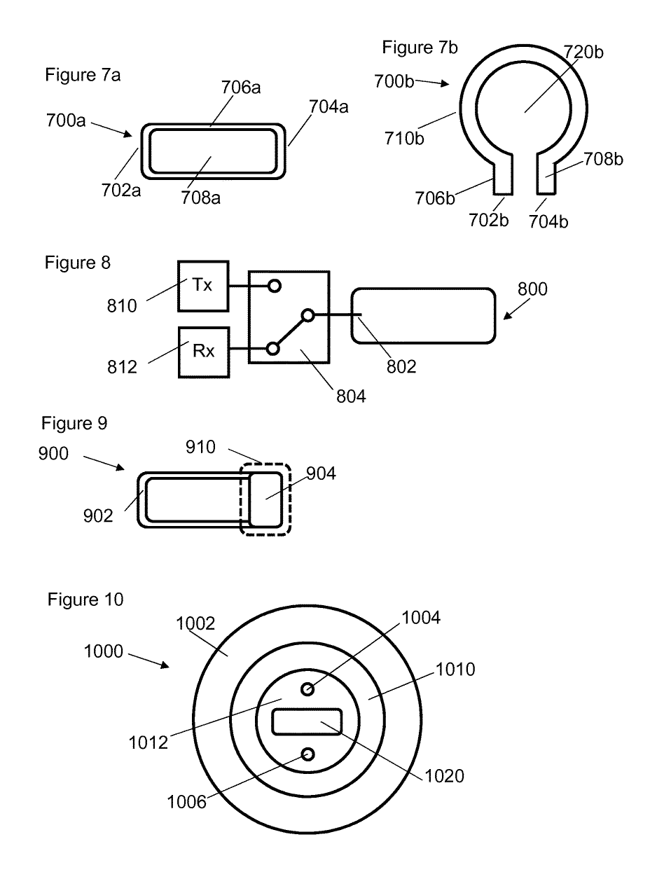

FIG. 7a illustrates an ionized gas plasma antenna with a linear containment envelope;

FIG. 7b illustrates an ionized gas plasma antenna with a circular containment envelope;

FIG. 8 illustrates a single ionized gas plasma antenna configured to function as both a transmitter and a receiver;

FIG. 9 illustrates an ionized gas plasma antenna with shielded metal components; and

FIG. 10 illustrates a combined magnetic resonance imaging and positron emission tomography apparatus.

Embodiments of the present disclosure relate to a magnetic resonance imaging (MRI) apparatus in which a plasma antenna is used to transmit and/or receive radio-frequency signalling to or from an object that is to be imaged. The plasma antenna may be a fluorescent lamp of the type that is known to provide light in domestic and commercial settings. Plasma antennae may advantageously be easily and cost effectively constructed and may not cause some undesired interference effects. For example, the plasma antennae can be provided with no or only limited exposed metallic components, which can enable the plasma antenna to be easily decoupled from other components in the system. This can therefore ease a task of coil building.

In some examples, embodiments of the present disclosure may relate to magnetic resonance spectroscopy (MRS) in which a plasma antenna is used to transmit and/or receive radio-frequency signalling to or from an object to be analysed to provide magnetic resonance spectra for the object. It will be appreciated that disclosures herein relating to magnetic resonance imaging may similarly apply to magnetic resonance spectroscopy, wherein the differences between the two techniques relate to characteristics of the magnetic system known to persons skilled in the art.

FIG. 1 shows a cross section view of a magnetic resonance imaging (MRI) apparatus 100 according to the present disclosure. The magnetic resonance imaging apparatus 100 comprises a magnetic system 102. In some examples, the magnetic system 102 comprises a tubular structure that surrounds a cavity 104 and provides a strong magnetic field within at least a portion of the cavity 106. The strength of the magnetic field may be between 1 Tesla and 10 Tesla, although other examples with weaker magnetic fields, such as 0.5 Tesla, or stronger magnetic fields, such as 15 Tesla or 20 Tesla, may also be provided. The magnetic field may interact with an object 108 placed within the portion of the cavity 106. In particular, the magnetic field may interact with the spin angular momenta of quantum particles contained within the object 108.

The magnetic system may comprise different components, such as a main magnet, configured to provide a homogeneous magnetic field and a magnetic gradient coil system configured to provide for spatial information of the radio-frequency-received-signal. The details of exemplary magnetic systems are known to persons skilled in the art.

The MRI apparatus 100 further comprises a radio frequency transmitter 120 disposed at least partially within the cavity 104. It will be appreciated that the transmitter 120 may be wholly disposed within the cavity, or some portion of the transmitter 120 may project outwards from the cavity. Further, the transmitter 120 may be partly or wholly disposed within the portion of the cavity 106. The transmitter 120 may be configured to transmit radio frequency electromagnetic signalling into the cavity 104. At certain frequencies the transmitted signalling may interact with spin angular momenta of the quantum particles contained within the object 108. The particular frequency of interaction depends on the magnetic field and the gyromagnetic ratio of the quantum particles concerned. For example, hydrogen ions (protons) will undergo a resonant interaction with radio frequency transmitted signalling at approximately 42.6 MHz T⁻¹, while unpaired electrons will undergo a similar resonant interaction at approximately 28 GHz T⁻¹. The consequences of these interactions may be measured by a suitable radio frequency receiver 122. The receiver 122 may be partly or wholly disposed within the cavity 104 or partly or wholly disposed within the portion of the cavity 106.

It will be appreciated that by providing a magnetic field with a gradient in field strength, different parts of the object 108 will experience different magnetic field strengths; different parts of the object 108 will therefore experience resonant interactions with the transmitted radio frequency signalling at different frequencies. By varying the magnetic field gradient and transmitted signalling according to a suitable sequence, it may be possible to measure signalling received by the receiver 122 that can be used to provide magnetic resonance imaging of the density of particular quantum particles within the object 108. The signal processing required to combine data representative of the magnetic field, data representative of the transmitted radio frequency signalling and data representative of the received radio frequency signalling, to provide magnetic resonance imaging of the object may be performed by a digital computer (not shown) or by any other means known to persons skilled in the art. Through the appropriate choice of magnetic fields and frequencies of transmitted signalling, the magnetic resonance imaging may be provided based on either nuclear magnetic resonance effects or electron spin resonance effects.

It will be appreciated that many different types of object 108 may be imaged using magnetic resonance imaging. The technique may be particularly advantageous when non-destructive investigation of biological systems is required. In some examples the object may be a human or animal patient. The patient's entire body may be imaged or some portion of the patient's body may be imaged. In other examples, inanimate objects may be imaged.

Advantageously, at least one of the transmitter 120 and the receiver 122 is a plasma antenna. Plasma antennae may be easily and cost effectively constructed, may not cause certain interference effects, and may advantageously be reconfigurable without the need for changes to the structure of the hardware, as discussed in more detail below. Also, the an MRI system using a plasma antenna can provide a particularly good signal to noise ratio (SNR), which can result in a better image or a shorter image capture time. These advantages can be very significant when imaging a human or animal patient that could move. The plasma antennae if used as a transmit antenna can beneficially be switched off during the duration of the reception, thus providing improved, and perhaps perfect, decoupling between the transmit and receiving systems. The switching off of plasma antennae can be used to improve decoupling in either a transmit or receive array consisting of a multitude of plasma antennae. This can enable plasma antennae for different nuclei to be built in close proximity to each other, which would otherwise be difficult to decouple if conventional antennae were used. Decoupling in that case would be provided by switching the plasma on only in an antennae that is required for a specific operation for either transmission or reception. Plasma antennae can also be configured to produce a switchable radio frequency shield allowing the shielding of an object, such as the arms of a human, from the radio frequency thus reducing the specific absorption rate as well as reducing imaging artefacts that might be caused by folding.

The fact that plasma antennae can be used in an MRI system is surprising because it was expected that the thermal noise that is generated by such a plasma antenna would render the plasma antenna too inefficient to be a viable choice. It has also been found that plasma antennae will not work if they are switched on prior to the antennae reaching their final position in the magnetic resonance imaging apparatus. A switched on plasma antennae is very likely to extinguish if it is moved through a strong magnetic field gradient as present in an MRI scanner. However, surprisingly, it has been found that by locating the plasma antenna in its final position before activating the magnetic field, the plasma antenna is usable as described in this document

In some examples, the transmitter 120 may be a first plasma antenna and the receiver antenna 122 may be a second plasma antenna. Using plasma antennae for both the transmitter 120 and receiver 122 may obviate problems associated with metal antennae in relation to both the transmitter 120 and the receiver 122. However, it will be appreciated that either one of the transmitter 120 or the receiver 122 may comprise metal components electromagnetically coupled to one another and may further comprise other solid state electronic components such as capacitors and inductors.

In some examples the transmitter 120 may comprise a plurality of plasma antennae. A plurality of plasma antennae may provide for a better distribution of transmitted signalling than a single plasma antennae may provide. Also, the receiver antenna 122 may comprise a plurality of plasma antennae. A plurality of plasma antennae may provide for superior reception of signalling from the object 108 being imaged, compared to reception that may be possible with a single plasma antenna.

FIG. 2 shows an example of a plasma antenna 200 that can be used in the MRI apparatus of FIG. 1. The plasma antenna 200 comprises a containment envelope 202 configured to contain a vapour 204, the vapour 204 suitable for forming an ionized gas plasma. The containment envelope 202 may comprise glass or plastic or any other suitable dielectric or insulating material known to persons skilled in the art. The vapour 204 may comprise a variety of different chemical species at various pressures, including any one or more of helium, neon, argon, krypton, xenon, hydrogen, mercury vapour, any other suitable chemical species known to persons skilled in the art, and mixtures thereof such as air.

The antenna 200 further comprises an energy supply 206. When in use, the energy supply 206 may supply sufficient energy to ignite the vapour 204 to form an ionized gas plasma. In some examples the energy supplied may only ignite some of the vapour 204 within the containment envelope 202. The amount of energy supplied to the vapour 204 may be varied such that a greater or lesser amount of plasma is ignited. In this way, it may be possible to change the length, and hence performance, of the ignited plasma in an advantageous way such as by controlling a field of view, setting a limited specific absorption rate, as well as providing improved spatial information.

In some examples the energy supply 206 may comprise electrodes, lasers, fibre optics, Radio Frequency heating, microwaves, ultraviolet radiation, high voltage signalling, electromagnetic couplers or other means known to persons skilled in the art. Where radio frequency electromagnetic energy is supplied to the plasma 202 it may be advantageous to provide an impedance matching circuit to provide for improved efficiency in supplying radio frequency power to the plasma 202. Such impedance matching circuits are known to those skilled in the art.

The plasma antenna 200 further comprises an electromagnetic coupling 208. In examples where the plasma antenna 200 is configured to act as a transmitter, the electromagnetic coupling 208 will be connected to a signal generator (not shown). In examples where the plasma antenna 200 is configured to act as a receiver the electromagnetic coupling 208 will be connected to a signal analyser (not shown). The electromagnetic coupling 208 may be coupled to the plasma 202 by being in sufficiently close proximity to the plasma or by a signal coupler or by any other mechanism known to persons skilled in the art.

The ionized gas plasma antenna 200 may be configured to provide effective reception and transmission of radio frequency signalling up to approximately 100 GHz.

In some examples an ionized gas plasma antenna may not have any containment envelope. For example, air at atmospheric pressures may provide an ionized gas plasma if supplied with energy suitable for igniting air to form a plasma. In some examples air, or another uncontained gas, may be ignited by focusing a laser beam to a sufficiently high intensity within a particular region. Radio frequency signalling may be provided to or received from such a plasma by an electrical coupling positioned within a suitable proximity to the plasma.

FIG. 3 shows an ionized gas plasma antenna 300, with a containment envelope 306 that has a proximal end 302 and a distal end 304. The containment envelope 306 is configured to contain a vapour 308 suitable for forming an ionized gas plasma. The ionized gas plasma antenna 300 further comprises a first electrode 310 disposed within the containment envelope 306 at the proximal end 302. The first electrode 310 is electrically coupled to a first terminal 312 disposed outside of the containment envelope 306. The ionized gas plasma antenna 300 further comprises a second electrode 314 disposed within the containment envelope 306 at the distal end 304. The second electrode 312 is configured to be electrically coupled to a second terminal 316 disposed outside of the containment envelope 306. An electrical voltage may be applied to the first terminal 312 and the second terminal 316 such that electrical power is supplied to the vapour 308 sufficient to ignite the vapour 308 to form an ionized gas plasma. The applied voltage may provide a direct current or an alternating current to the ionized gas plasma.

One or both of the first terminal 312 and the second terminal 316 may also be configured to supply or receive radio frequency signalling to or from the ionized gas plasma. In this way, an electrode can be used to communicate radio-frequency-transmitted-signalling or radio-frequency-received-signalling. Alternatively, other mechanisms known to persons skilled in the art may be used to provide for communication of radio frequency signalling to or from the ionized gas plasma ionized gas plasma.

FIG. 4 shows an ionized gas plasma antenna 400 with a containment envelope 406 having a proximal end 402 and a distal end 404. The containment envelope 406 is configured to contain a vapour 408 suitable for forming an ionized gas plasma when ignited. The ionized gas plasma antenna 400 includes an electrode 410 disposed at the proximal end 402. In other examples (not shown) the electrode 410 may be disposed within any other part of the containment envelope 406. The electrode 410 has a first end 420 electrically coupled to a first terminal 422 disposed outside of the containment envelope 406. The electrode 410 also has a second end 424 electrically coupled to a second terminal 426 disposed outside of the containment envelope 406. A voltage may be applied to the first terminal 422 and the second terminal 426 such that electrical power is supplied to the vapour 408 by the electrode so as to ignite the vapour 408 to form an ionized gas plasma. The first terminal 422 and/or the second terminal 426 may also be configured to supply or receive radio frequency signalling to or from the plasma antenna 400. In some examples the electrode 410 may be configured to supply radio frequency signalling that provides for both transmitted radio frequency signalling and for ignition of the plasma, particularly if the supplied radio frequency signalling is in the MHz frequency range.

In some examples the ionized gas plasma antenna 400 may have a second electrode (not shown). The second electrode may be located at any suitable position within the containment envelope 406. In some examples a second electrode may be located at the distal end 404 of the containment envelope 406 with suitable terminals disposed outside of the containment envelope in electrical communication with the second electrode as for the electrode 410 disposed at the proximal end 402 of the containment envelope 406.

One or more of the plasma antennae disclosed herein may comprise fluorescent tubes of the type conventionally used for lighting purposes. Fluorescent tubes may provide readily available and cost effective examples of plasma antennae. Since many different type of fluorescent tube are available, it may be easily possible to select different tubes that are most suitable for different applications as either receivers or transmitters in relation to a wide range of different types of objects that may be imaged using magnetic resonance imaging techniques.

FIG. 5 shows an ionized gas plasma antenna 500 that is similar to the ionized gas plasma antenna of FIG. 4. As with the antenna of FIG. 4, the ionized gas plasma antenna 500 of FIG. 5 has a containment envelope 506 with a proximal end 502 and a distal end 504. The antenna 500 has a first electrode 510 disposed at the proximal end 502. The first electrode 510 has a first end 520 that is electrically coupled to a first terminal 522 disposed outside of the containment envelope 506. The first electrode 510 also has a second end 524 in this example, which is electrically floating within the containment envelope 506. That is, in this example, the first electrode 510 is only connected to one terminal outside of the containment envelope 506.

The antenna 500 has a second electrode 530 disposed outside of the containment envelope 506 and electrically coupled to a second terminal 532. That is, the second electrode 530 is not in direct contact with the vapour 508. In some examples the second electrode 530 may form a continuous loop (not shown) around the containment envelope 506 proximal to the first electrode 510. The second electrode 530 may be galvanically isolated from the first electrode 510. It will be appreciated that application of a suitable voltage across the first terminal 522 and second terminal 532 may provide electrical power to the vapour 508 since a sufficiently high electric field between the first electrode 510 and the second electrode 530 may cause current to flow within the vapour 508. This current may be configured to provide a high voltage spark ignition of the vapour 508 to form an ionized gas plasma. That is, the second electrode 530 is in sufficiently close proximity to the vapour 508 for it to provide electrical power to the vapour 508 in order to ignite the vapour. As above, one or both of the first terminal 522 and the second terminal 532 may be configured to provide radio frequency signalling to or from the antenna 500.

FIG. 6 shows an ionized gas plasma antenna 600 having a containment envelope 606 configured to contain a vapour 608 suitable for forming an ionized gas plasma when ignited. The antenna 600 includes an igniter 640, disposed outside of the containment envelope 606. That is, the igniter 640 is not in direct contact with the vapour 508. The igniter 640 is configured to provide an energy supply 642 to the vapour 608 suitable for igniting the vapour 608 to form an ionized gas plasma. It will be appreciated that a variety of possible igniters may be used in this way. In some examples the igniter 640 may comprise a laser, a microwave source, an ultraviolet source, or a tesla coil. In some examples the igniter 640 may be configured to supply radio frequency electromagnetic energy to the vapour 608. Radio frequency electromagnetic energy may provide radio frequency heating of the vapour 608 in order to ignite an ionized gas plasma. Once a plasma has been ignited within the containment envelope 606, radio frequency signalling may be provided to or received from the antenna 600. In some examples the radio frequency signalling may be coupled into or out of the containment envelope 606 by an electromagnetic coupler 650 or by any other suitable mechanism known to persons skilled in the art.

It will be appreciated that the plasma antennae disclosed above may have one or two sources of energy for igniting the plasma; either or both of (i) the electrodes described with reference to FIGS. 2 to 5; and (ii) the igniter of FIG. 6. In general, any of the ionized gas plasma antennae disclosed herein may be provided with a plurality of sources of energy for igniting vapour contained within a containment envelope to form ionized gas plasma. In some examples there may be a plurality of electrodes or a plurality of pairs of electrodes provided for supplying energy to different portions of vapour within a containment envelope. In some examples there may be provided a plurality of external igniters for supplying energy to different portions of vapour within a containment envelope. In this way, by selectively supplying energy to different combinations of energy supply mechanisms it may be possible to ignite different portions of vapour within a single containment envelope. Thereby, a single containment envelope may be configured to provide different lengths or geometries of plasma for transmitting or receiving radio frequency signalling. Particular geometries of plasma may be selected according to the particular characteristics of an object to be imaged. It will be appreciated that different portions of plasma, even within the same containment envelope, may be provided with separate electromagnetic couplings to provide for transmission or supply of radio frequency signalling required for magnetic resonance imaging, based on the characteristics of the object to be imaged.

FIGS. 7a and 7b each show an ionized gas plasma antenna 700a, 700b with a containment envelope 706a, 706b configured to contain a vapour 708a, 708b suitable for providing an ionised gas plasma when ignited. The containment envelope 706a, 706b may comprise at least one of: (i) a linear envelope 706a, comprising a distal end 702a and a proximal end 704a spaced apart longitudinally, the containment envelope extending therebetween; and (ii) a circular envelope 706b, comprising a loop of containment envelope 710b extending around a central void 720b.

FIG. 7a shows an ionized gas plasma antenna 700a with a linear containment envelope 706a having a proximal end 702a and a distal end 704a. The linear containment envelope extends between the proximal end 702a and the distal end 704a which are spaced apart longitudinally. In some examples the linear containment envelope 706a may be straight, in that the containment envelope 706a may extend in a straight configuration between the proximal end 702a and the distal end 704a. However, in other examples the containment envelope 706a may comprise a curved configuration or may comprise bends or angles between the proximal end 702a and the distal end 704a.

FIG. 7b shows an ionized gas plasma antenna 700b with a circular containment envelope 706b having a proximal end 702b and a distal end 704b. The circular containment envelope 706b extends between the proximal end 702b and the distal end 704b, in this example along a curved path in a single plane. The circular containment envelope 706b comprises a loop 710b of containment envelope that extends around a central void 720b. The loop 710b of containment envelope may be circular, square, rectangular or elliptical or any other planar shape in configuration. In some examples the loop may extend out of a particular plane by for example forming a helix (not shown) that surrounds a central void. Such circular containment envelopes may provide for more efficient transmission to or reception from a particular object being imaged, of the radio frequency signalling required to construct a magnetic resonance image. Improvements in efficiency or signal to noise ratio may be achieved by selecting a size of loop suitable for surrounding the object to be imaged.

In one or more of the examples disclosed herein, the plasma antenna may transmit or receive in-phase and quadrature RF signals, optionally simultaneously. Quadrature signalling, comprising in-phase and quadrature signalling that 90 degrees out of phase with each other may be provided to a single electrode or a pair of electrodes within any plasma antenna. In some examples the quadrature signalling may be provided to electrodes situated at the proximal end and distal end of a containment envelope such as that disclosed in relation to FIGS. 3 and 7a.

In FIG. 7b, electrodes (not shown) may be provided at the proximal end 702b and the distal end 704b of the circular containment envelope 706b. The electrodes at opposite ends may be provided with radio frequency power with a 90 degree phase shift between the electrodes. Such a 90 degree phase shift may drive the antenna in quadrature. Quadrature drive may provide for circularly polarised radio frequency signalling, for example.

As indicated above, separate plasma antennae can be used for receiving and transmitting RF signalling, that is, a separate transmitter antenna and received antenna can be provided. The transmitter antenna may be in the form of a first ionized gas plasma antenna comprising a first containment envelope that contains a first vapour. The first vapour may be suitable for forming a first ionized gas plasma. The receiver antenna may be in the form of a second ionized gas plasma antenna comprising a second containment envelope configured to contain a second vapour suitable for forming a second ionized gas plasma. The second vapour may be different to the first vapour.

Use of different vapours to form the ionized gas plasma for the transmitter and receiver antennae respectively may allow for greater efficiency or superior signal to noise ratios of the transmitter or receiver. Different vapours may comprise different chemical species or a plurality of chemical species in different proportions or different pressures of vapour.

The composition of vapour can affect the characteristics of the plasma antenna in both the transmit mode and receive mode equally. These characteristics are thermal noise, pulsing rate if used to ionize the gas, and the range of the plasma frequency. The lower the collision rate in the plasma whether fully or partially ionized, the lower the thermal noise. The heavier the noble inert gas used for ionization, the longer the relaxation time and the lower the frequency of pulses needed to ionize the gas with effective constant density. The smaller the percentage of ionized gas to operate the plasma antenna the greater the range of the plasma frequency. For example when a commercial fluorescent tube works as a plasma antenna only a small percentage of the gas is ionized. The plasma frequency can be greater than the operating plasma antenna frequency. If all the plasma in a commercially fluorescent tube were ionized, the plasma frequency could be in the terahertz frequency and the fluorescent tube then could operate as a terahertz plasma antenna.

Different choices of vapour may also provide for more appropriate radio frequency signalling based on the nature of the object to be imaged or based on the particular quantum particles selected for the imaging process. For example, a first plasma may be more suitable for transmitting and/or receiving in the frequency range suitable for imaging based on hydrogen ions (or other types of nuclear magnetic resonance imaging) while a second plasma may be more suitable for transmitting and/or receiving in the frequency range suitable for electron spin resonance imaging.

The frequency of operation can be determined by the plasma frequency which should be greater than the operating frequency. The plasma frequency is the natural oscillation of the plasma if the positive ions were separated from the electrons and the system oscillated under the restoring force. The plasma frequency increases with the amount of ionization and is proportional to the square root of the density of unbound electrons or ionization. If a pulsing technique is used to ionize the gas, the heavier the noble or inert gas, the longer the plasma relaxation time, and the longer the time interval can be between pulses to yield an effectively constant plasma density gas.

FIG. 8 shows a plasma antenna 800 suitable for a magnetic resonance imaging apparatus, wherein the transmitter antenna is also the receiver antenna. That is, a single plasma antenna 800 is used as both the transmitter antenna and the receiver antenna. In this way, a single electrode electromagnetic coupler 802 can be used to communicate both radio-frequency-transmitted-signalling and radio-frequency-received-signalling

The plasma antenna 800 is provided with an electromagnetic coupler 802 or other suitable means for providing radio frequency signalling to or from the antenna 800. The electromagnetic coupler is connected to a switch 804. The switch 804 is coupled to a transmitter 810 and a receiver 812. The switch 804 is operable to selectively connect the electromagnetic coupler 802 either to the transmitter 810 or to the receiver 812. In this example, when the electromagnetic coupler 802 is connected to the transmitter 810 it is disconnected from the receiver 812, and vice versa. When the electromagnetic coupler 802 is connected to the transmitter 810, the transmitter 810 may provide radio frequency transmitter signalling to the plasma antenna 800. When the electromagnetic coupler 802 is connected to the receiver 812, radio frequency signals received by the plasma antenna 800 may be communicated to the receiver 812. The transmitter 810, the receiver 812 and the switch 804 may be of any appropriate type known to persons skilled in the art to provide the necessary transmission, reception and switching. In some examples the switch may comprise high speed transistors configured to provide for switching according to appropriate time scales.

The transmitter 810 may optionally be configured to provide in-phase and quadrature radio-frequency-transmitted-signalling. Similarly, the receiver 812 may optionally be configured to receive in-phase and quadrature radio-frequency-received-signalling.

Use of a combined transmitter and receiver, or transceiver, may also provide the advantage of requiring fewer component parts than systems using separate transmitters and receivers. Also, using the same antenna for both transmission and reception may advantageously allow for a physically small arrangement of transmitter and receiver to be provided, which may be advantageous as the single antenna may occupy less space than a pair of antennas. Also, a small antenna can be particularly suitable for use in a void within an object in order to provide for images of the parts of the object proximal to the void within the object. That is, the antenna can be used to image outwards into the object from within the void.

FIG. 9 shows a plasma antenna 900 comprising non-metallic components 902, such as a glass containment envelope, and at least one metallic component 904, for example electrical connections between an electrode and a co-axial cable that is used to provide signals to the electrode. FIG. 9 shows a shielding 910 that surrounds or partially surrounds the at least one metallic component 904. This shielding 910 can advantageously reduce or prevent the associated magnetic system (not shown) having an effect on the at least one metallic component 904. In some examples the shielding 910 may comprise a splitted copper shield or other shield types known to people skilled in magnetic resonance transceiver design.

FIG. 10 shows a cross section view of a magnetic resonance imaging apparatus 1000 comprising a magnetic system 1002 configured to provide a magnetic field to a cavity. Within the cavity there is provided a Positron Emission Tomography (PET) scanner 1010, having a void 1012 for receiving an object 1020 to be scanned. Within the void 1012 there may be disposed a transmitter antenna 1004 and a receiver antenna 1006 configured to provide radio frequency signalling to and from the object 1020. The transmitter antenna 1004 and receiver antenna 1006 may comprise plasma antennae such as any of the ionized gas plasma antennae disclosed above. The PET scanner 1010 may advantageously not interfere with the magnetic field provided by the magnetic system 1002. Thereby, the apparatus may provide magnetic resonance imaging of the object 1020.

If either of the transmitter antenna 1004 or receiver antenna 1006 comprise metal components, the metal components may interfere with signalling detectable by the PET scanner 1010. However, if plasma antennae are used for the transmitter antenna 1004 and receiver antenna 1006 then they may contain little or no metal and may therefore not interfere significantly with the acquisition of the signalling required for PET scanning. In this way, it may advantageously be possible to provide simultaneous imaging of the same object 1020 using both magnetic resonance imaging and PET scanning. In some examples the object 1020 to be imaged and scanned may be a human or animal patient. Provision of both types of imaging and scanning simultaneously may aid in the detection, identification and/or diagnosis of certain medical conditions that may be more difficult or impossible to determine without both magnetic resonance imaging and PET scanning.

A plasma antenna that does not include any exposed metal parts can be considered as being capable of “disappearing” when the plasma is turned off, which can be particularly advantageous for PET-MRI systems.

It will be appreciated that in addition to, or instead of, the PET scanner 1010 of FIG. 10, a Single-Photon Emission computed tomography scanner and/or a computed tomography scanner can be disposed within the cavity, where each of these scanners also has a void for receiving the object 1020 to be scanned.

In addition to, or instead of, plasma antennae being used as a transmitter antenna and/or a receiver antenna, a magnetic gradient system may also comprise a plasma antenna configured to provide magnetic field gradients. Use of a plasma antenna to provide a magnetic field gradient may enable replacement of metal conductor-based gradient coils in a magnetic resonance imaging or nuclear magnetic resonance system. This may further improve integration of PET-MRI systems and/or combined Single-Photon Emission computed tomography (or other types of computed tomography scanner) and Magnetic Resonance Imaging (MRI or NMR) systems, as the gradient system may also be rendered electromagnetically ‘invisible’ when the plasma is turned off.

It will be appreciated that any components that are described herein as being coupled or connected could be directly or indirectly coupled or connected. That is, one or more components could be located between two components that are said to be coupled or connected whilst still enabling the required functionality to be achieved.

The term “signalling” may refer to one or more signals transmitted as a series of transmitted and/or received signals. The series of signals may comprise one, two, three, four or even more individual signal components or distinct signals to make up said signalling. Some or all of these individual signals may be transmitted/received simultaneously, in sequence, and/or such that they temporally overlap one another.

1. A magnetic resonance apparatus comprising:
a magnetic system configured to provide a magnetic field throughout at least a portion of a cavity, the magnetic field based on magnetic-system-control-data;
a transmitter antenna disposed at least partly within the cavity and configured to transmit radio-frequency-transmitted-signalling based on transmitter-control-data; and
a receiver antenna disposed at least partly within the cavity and configured to receive radio-frequency-received-signalling representative of magnetic resonance interactions of at least one object, disposed within the portion of the cavity, with the magnetic field and the radio-frequency-transmitted-signalling;
wherein:
at least one of the transmitter antenna, the receiver antenna and the magnetic system comprises a plasma antenna; and
the magnetic resonance imaging apparatus is configured to provide received-data representative of the radio-frequency-received-signalling, the received-data in combination with the magnetic-system-control-data and the transmitter-control-data, wherein the received-data is suitable for providing magnetic resonance imaging and/or magnetic resonance spectroscopy of the at least one object.

2. The magnetic resonance apparatus of claim 1, wherein the transmitter antenna is a first plasma antenna and/or the receiver antenna is a second plasma antenna.

3. The magnetic resonance apparatus of claim 1, wherein one or both of the transmitter antenna and the receiver antenna comprises a plurality of plasma antennae.

4. The magnetic resonance apparatus of claim 1, wherein the plasma antenna comprises an ionized gas plasma antenna with a containment envelope configured to contain a vapour, the vapour suitable for forming an ionized gas plasma.

5. The magnetic resonance apparatus of claim 4, wherein the ionized gas plasma antenna comprises a first electrode contained within the containment envelope and a second electrode, wherein the first electrode is configured to communicate the radio-frequency-transmitted-signalling and/or the radio-frequency-received-signalling.

6. The magnetic resonance apparatus of claim 5, wherein the first electrode is configured to communicate in-phase and quadrature phase radio-frequency-transmitted-signalling or radio-frequency-received-signalling.

7. The magnetic resonance apparatus of claim 5, the containment envelope having a proximal end and a distal end, wherein the first electrode is contained within the proximal end of the containment envelope and is in electrical communication with a first terminal disposed outside of the containment envelope; the ionized gas plasma antenna further comprising:
a second electrode contained within the distal end of the containment envelope, wherein the second electrode is in electrical communication with a second terminal disposed outside of the containment envelope;
wherein the first terminal and the second terminal are configured to supply at least one of a Direct Current and an Alternating Current to the ionized gas plasma antenna.

8. The magnetic resonance apparatus of claim 5, the containment envelope having a proximal end and a distal end, wherein the first electrode is in electrical communication with a first terminal disposed outside of the containment envelope; and
the ionized gas plasma antenna further comprising:
a second electrode disposed outside of the containment envelope and galvanically isolated from the first electrode, wherein the second electrode is in electrical communication with a second terminal disposed outside of the containment envelope;
wherein, the first terminal and the second terminal are configured to provide electrical power to the ionized gas plasma antenna.

9. The magnetic resonance apparatus of claim 5, wherein the ionized gas plasma antenna further comprises an igniter, disposed either outside or inside of the containment envelope, for igniting the vapour to form the ionized gas plasma, wherein the igniter comprises one or more of:
a laser;
a device producing a static/alternating magnetic field such as a tesla coil;
a high or low voltage Direct Current source;
a high or low voltage Alternating Current source;
a radio frequency source; and
a microwave source.

10. The magnetic resonance apparatus of claim 5, wherein the containment envelope comprises at least one of:
a linear envelope, comprising a distal end and a proximal end spaced apart longitudinally, the containment envelope extending therebetween; and
a curved envelope, comprising a loop of containment envelope extending around a central void.

11. The magnetic resonance apparatus of claim 1, wherein:
the transmitter antenna is a first ionized gas plasma antenna comprising a first containment envelope configured to contain a first vapour, the first vapour suitable for forming a first ionized gas plasma; and
the receiver antenna is a second ionized gas plasma antenna comprising a second containment envelope configured to contain a second vapour, different than the first vapour, the second vapour suitable for forming a second ionized gas plasma, wherein the second ionized gas plasma is different to the first ionized gas plasma.

12. The magnetic resonance apparatus of claim 1, wherein the transmitter antenna is also the receiver antenna.

13. The magnetic resonance apparatus of claim 1, wherein the plasma antenna comprises metal components and a shielding, wherein the shielding is configured to electromagnetically shield the metal components from the magnetic field in the cavity.

14. The magnetic resonance apparatus of claim 1, further comprising at least one of:
a Positron Emission Tomography scanner disposed within the cavity, the Positron Emission Tomography scanner having a void for receiving an object to be scanned;
a Single-Photon Emission computed tomography scanner disposed within the cavity, the Single-Photon Emission computed tomography scanner having a void for receiving an object to be scanned; and
a computed tomography scanner disposed within the cavity, the computed tomography scanner having a void for receiving an object to be scanned;
wherein the transmitter antenna and the receiver antenna are disposed within the void.

15. The magnetic resonance apparatus of claim 1, wherein the magnetic system comprises a magnetic gradient system, wherein the magnetic gradient system comprises a plasma antenna configured to provide magnetic field gradients.

16. The magnetic resonance apparatus of claim 1, wherein the plasma antenna comprises a fluorescent tube.

17. (canceled)
